(19) United States
(12) Patent Application Publication
(10) Pub. No.: US 2011/0227224 A1
(43) Pub. Date: Sep. 22, 2011

(54) Semiconductor device and method for manufacturing the same

(75) Inventor: Ryohei Kitao, Kanagawa (JP)

(73) Assignee: Renesas Electronics Corporation, Kawasaki-shi (JP)

(21) Appl. No.: 12/929,799

(22) Filed: Feb. 16, 2011

(30) Foreign Application Priority Data
Mar. 19, 2010 (JP) 2010-064413

(51) Int. Cl. H01L 23/532; H01L 21/768

(52) U.S. Cl. 257/751; 438/643; 257/E23.155; 257/E21.585

(57) ABSTRACT

A semiconductor device includes an interlayer insulating film formed over a semiconductor substrate, a through hole formed in the interlayer insulating film, a Cu film filling the through hole, and a metal-containing base film formed on the sidewall inside the through hole and serving as a base of the Cu film. The metal-containing base film has a metal nitride layer at the interface with the Cu film in a first region including a sidewall area adjacent to the opening of the through hole. In a second region including a sidewall area nearer to the semiconductor substrate than is the first region, the metal-containing base film has a metal layer at the interface with the Cu film. The deposition rate of the Cu film on the surface of the metal layer is greater than the deposition rate of the Cu film on the surface of the metal nitride layer.

### CROSS-REFERENCE TO RELATED APPLICATION

The disclosure of Japanese Patent Application No. 2010-64413 filed on Mar. 19, 2010 including the specification, drawings and abstract is incorporated herein by reference in its entirety.

### BACKGROUND

1. Field of the Invention

The present invention relates to a semiconductor device and a method for manufacturing the semiconductor device.

2. Description of Related Art

With the miniaturization of interconnections in recent years, through holes coupling a semiconductor substrate and interconnects are becoming smaller and smaller. Such minute through holes may be a cause of contact resistance affecting the operating speed of a semiconductor device, the contact resistance being not negligible.

Japanese Unexamined Patent Publication No. 2008-130931 describes a technique of cleaning the bottom of a through hole having a metal nitride film deposited on the internal sidewall thereof. The publication explains that the technique prevents an interlayer insulating film from being excessively etched by an etchant and maintains the opening width of the through hole within a predetermined range, thereby making the contact geometry small and reducing resistance variations.

Japanese Unexamined Patent Publication No. 2009-10037 describes the formation of a thin barrier film made of tantalum nitride by an ALD method in a formation process of a minute Cu contact plug. The publication explains that the technique allows the filling of copper in a through hole of 0.1 μm in diameter.

Japanese Unexamined Patent Publication No. Hei 6 (1994)-112157 describes nitriding at least the surface of a metal thin film over an insulating film and the formation of a metal silicide film mainly containing a thin metal film over the bottom of a through hole. The publication explains that the technique can form a metal silicide film having a uniform thickness regardless of the size of the through hole and curb the increase in contact resistance.

### SUMMARY

However, it was found that further miniaturization of interconnections creates voids and seams in the formation of the contact plug with the techniques of the above references. This is conceivably because the increased aspect ratio of the through hole causes a marked difference between the amounts of source gas supplied to the vicinity of the opening of the through hole and to the vicinity of the bottom of the through hole. Even with the above-mentioned techniques, the higher amount of the source gas supplied to the vicinity of the opening relatively accelerates the deposition rate on the sidewall in the vicinity of the opening, and the through hole is closed before the lower part of the through hole is filled up. This seems to be a cause of the voids and seams.

In addition, it is difficult to apply film formation techniques used for interconnections to fill up the through hole that has a smaller opening than openings of the interconnect holes.

A semiconductor device provided according to an aspect of the present invention includes:

an insulating film formed over a substrate;

a hole formed in the insulating film;

a metal film filling the hole; and

a metal-containing base film formed on a sidewall inside the hole and serving as a base of the metal film, in which

in a first region including a sidewall area, in the sidewall inside the hole, adjacent to an opening of the hole, the metal-containing base film has a first layer at an interface with the metal film,

in a second region including a sidewall area, in the sidewall inside the hole, nearer to the substrate than is the first region, the metal-containing base film has a second layer at an interface with the metal film, and

the deposition rate of the metal film on the surface of the second layer is greater than the deposition rate of the metal film on the surface of the first layer.

A method for manufacturing a semiconductor device provided according to another aspect of the present invention includes:

forming an insulating film over a substrate;

forming a hole in the insulating film; and

filling the hole with a metal film, in which

after the forming the hole in the insulating film and before the filling the hole with the metal film, forming a metal-containing base film on a sidewall inside the hole is included, the metal-containing base film serving as a base of the metal film,

the metal-containing base film has a first layer in a first region including a sidewall area, in the sidewall inside the hole, adjacent to an opening of the hole and a second layer in a second region including a sidewall area, in the sidewall inside the hole, nearer to the substrate than is the first region, and

in the filling the hole with the metal film, the metal film is formed over the metal-containing base film so that the metal film on the surface of the second layer is formed at a deposition rate greater than that at which the metal film on the surface of the first layer is formed.

According to the invention, the metal film is formed over the sidewall area adjacent to the opening of the through hole with the first layer as a base, while the metal film is formed over the sidewall area near the substrate with the second layer as a base. The deposition rate of the metal film on the surface of the second layer is greater than the deposition rate of the metal film on the surface of the first layer. The through hole can be therefore filled with the metal film from the sidewall area near the substrate, thereby realizing a void/seam resistant structure.

According to the present invention, the void/seam resistant structure can make excellent electrical coupling between a substrate and interconnects.

### BRIEF DESCRIPTION OF THE DRAWINGS

Embodiments of the present invention will be described in detail based on the following figures, wherein:

FIG. 1 is a schematic cross-sectional view of a semiconductor device according to the first embodiment;

FIG. 2 is a flow chart describing a method for manufacturing the semiconductor device according to the first embodiment;

FIG. 3 is a schematic cross-sectional view illustrating the method for manufacturing the semiconductor device according to the first embodiment;

FIG. 4 is a schematic cross-sectional view illustrating the method for manufacturing the semiconductor device according to the first embodiment;

FIG. 5 is a schematic cross-sectional view illustrating the method for manufacturing the semiconductor device according to the first embodiment;

FIG. 6 is a schematic cross-sectional view illustrating the method for manufacturing the semiconductor device according to the first embodiment;

FIG. 7 is a schematic cross-sectional view illustrating the method for manufacturing the semiconductor device according to the first embodiment;

FIG. 8 is a schematic cross-sectional view illustrating the method for manufacturing the semiconductor device according to the first embodiment;

FIG. 9 is a schematic cross-sectional view illustrating the method for manufacturing the semiconductor device according to the first embodiment;

FIG. 10 is a schematic cross-sectional view illustrating the method for manufacturing the semiconductor device according to the first embodiment;

FIG. 11 is a schematic cross-sectional view illustrating a method for manufacturing a semiconductor device according to the second embodiment;

FIG. 12 is a schematic cross-sectional view illustrating the method for manufacturing the semiconductor device according to the second embodiment;

FIG. 13 is a flow chart describing the method for manufacturing the semiconductor device according to the second embodiment;

FIG. 14 is a schematic cross-sectional view illustrating a method for manufacturing a semiconductor device according to the third embodiment;

FIG. 15 is a flow chart describing the method for manufacturing the semiconductor device according to the third embodiment;

FIG. 16 is a schematic cross-sectional view illustrating a method for manufacturing a semiconductor device according to the fourth embodiment;

FIG. 17 is a flow chart describing the method for manufacturing the semiconductor device according to the fourth embodiment; and

FIG. 18 is a schematic cross-sectional view illustrating the structure of a semiconductor device related to the embodiments.

### DETAILED DESCRIPTION OF THE PREFERRED EMBODIMENTS

With reference to the drawings, embodiments of the present invention will be described below. Like elements are denoted with the same reference numbers, and unless it is necessary, will not be further explained.

### First Embodiment

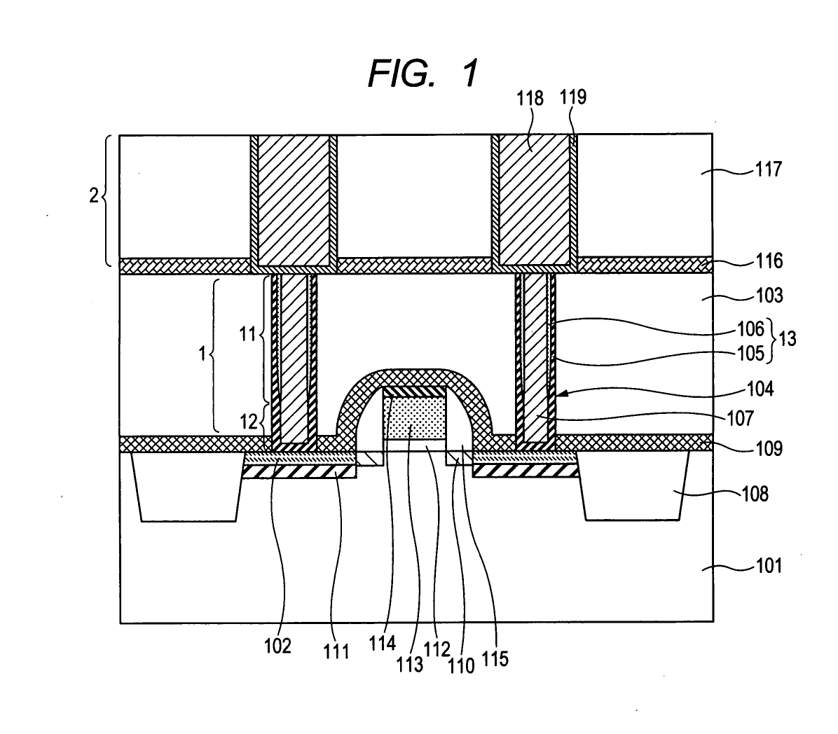

FIG. 1 is a schematic cross-sectional view illustrating a semiconductor device of the first embodiment. The semiconductor device of the embodiment includes an interlayer insulating film 103 formed over a semiconductor substrate 101, through holes (holes) 104 formed in the interlayer insulating film 103, Cu films 107 (metal films) filling the through holes 104, and metal-containing base films 13 formed over sidewalls inside the through holes 104 to serve as base films of the Cu films 107. Each metal-containing base film 13 includes a metal nitride layer 106 (first layer) at the interface with the Cu film 107 in a first region 11 that includes a sidewall area, in a sidewall of the through hole, adjacent to the opening of the through hole 104. The metal-containing base film 13 includes a metal layer 105 (second layer) at the interface with the Cu film 107 in a second region 12 that includes a sidewall area, in the sidewall of the through hole, nearer to the semiconductor substrate 101 than is the first region 11. The Cu film 107 on the surface of the metal layer 105 is formed at a deposition rate greater than that at which the Cu film 107 is formed on the surface of the metal nitride layer 106. In this embodiment, the deposition rate of the Cu film 107 is a rate at which the Cu film is deposited by a CVD (chemical vapor deposition) method.

The semiconductor device of the embodiment will be described in detail below. The semiconductor substrate 101 has a transistor element formed thereon. The transistor element includes, for example, as shown in FIG. 1, a lightly-doped diffusion layer 110, a gate insulating film 112, a gate electrode 113, a silicide layer 114, and a sidewall insulating film 115. A silicide layer 102 is formed on a heavily-doped diffusion layer 111. In this embodiment, the metal layer 105 formed at the bottom of the through hole 104 makes contact with the silicide layer 102. The element is electrically isolated by element isolation regions 108. In order to enhance adhesion between the semiconductor substrate 101 and interlayer insulating film 103, an insulating film 109, such as a SiN film, is formed between the transistor element and interlayer insulating film 103. An interconnection structure 2 is formed over the interlayer insulating film 103.

The through holes 104 are filled with the Cu films 107 to form contact plugs 1. The contact plugs 1 couple the source/drain region or gate electrode 113 of the transistor element and Cu interconnects 118 formed in the interconnection structure 2. The aspect ratio of the through hole 104 is preferably 3 to 10. The aspect ratio in this description is a ratio of the depth of the through hole to the diameter of the opening of the through hole. More specifically, the through hole 104 preferably has an opening diameter of 30 nm to 90 nm and a depth of 200 nm to 600 nm. The Cu interconnects 118 electrically coupled with the contact plugs 1 are formed by filling copper films in trenches having an opening diameter of 30 nm to 3000 nm and a depth of 90 nm to 200 nm.

The metal layer 105 can be a barrier metal film that prevents Cu of the Cu film 107 from diffusing into the interlayer insulating film 103. In addition, the metal layer 105 preferably has a crystal structure, e.g., a face centered cubic lattice structure (fcc structure) or a hexagonal close-packed structure (hcp structure). Using such a metal layer 105 as a base increases the deposition rate of the Cu film 107 deposited through the CVD method. Specifically, the metal layer 105 can be made of mainly cobalt (Co) or titanium (Ti), for example, and the Co or Ti content in the metal layer 105 is preferably 90% by weight or more. This can form an hcp-structure metal layer 105 capable of preventing Cu diffusion from the Cu film 107. The crystal structure of the metal layer 105 can be analyzed by an X-ray diffraction method or through an electron diffraction pattern obtained by a TEM (Transmission Electron Microscope). If the metal layer 105 cannot prevent Cu diffusion, a metal film, for example a tantalum nitride (TaN) film, capable of preventing Cu diffusion, can be deposited on the metal layer 105.

The Cu film 107 is preferably a metal film containing Cu as a main ingredient, and more specifically has a Cu content of 90% by weight or more.

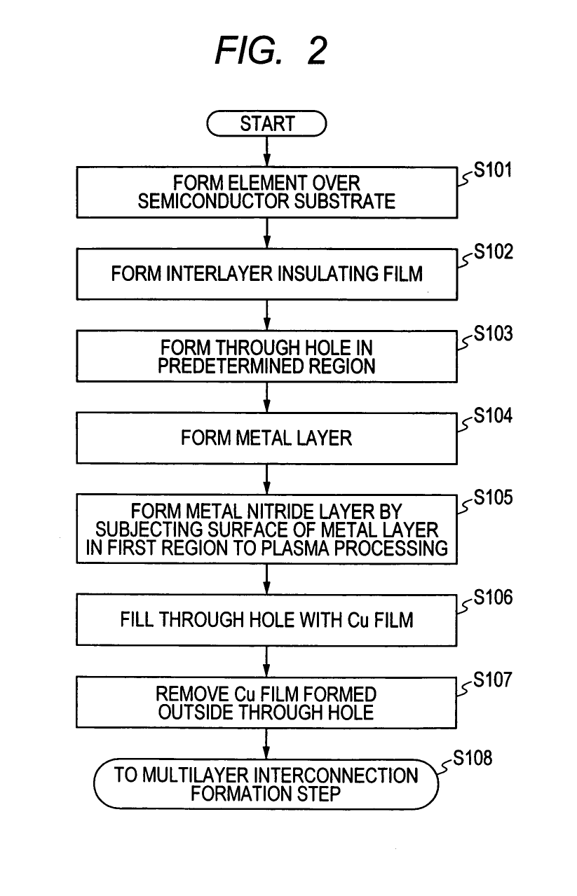

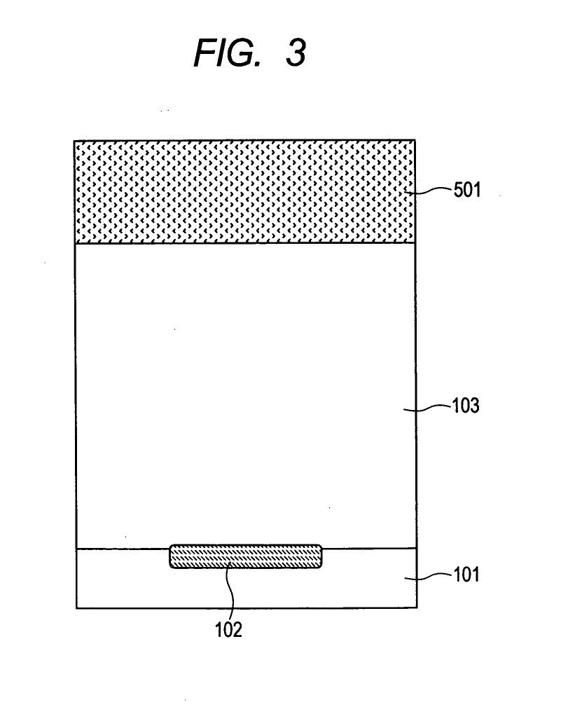

Following is a description about an exemplary method for manufacturing the semiconductor device of the embodiment with reference to FIGS. 1 to 10. FIG. 2 is a flow chart describing the method for manufacturing the semiconductor device of the embodiment. FIGS. 3 to 10 are schematic cross-sectional views illustrating the method for manufacturing the semiconductor device of the embodiment. First of all, an element (not shown), such as a transistor, is formed over a semiconductor substrate 101 using a known photolithography technique, dry etching technique, ion implantation technique, CVD technique or other methods (S101). On a heavily-doped diffusion layer region 111 on a semiconductor substrate 101, a silicide layer 102 is formed. An interlayer insulating film 103 is then formed over the semiconductor substrate 101 by a CVD method (S102) and is planarized by a CMP (Chemical Mechanical Polishing) method. The interlayer insulating film 103 may be, for example, a low-dielectric film, such as a silicon oxide film, having a dielectric constant of 4 or less. The interlayer insulating film 103 can be formed on an etch stop (not shown) formed over the semiconductor substrate 101. Subsequently, a predetermined pattern of a resist film 501 is formed on the interlayer insulating film 103 (FIG. 3).

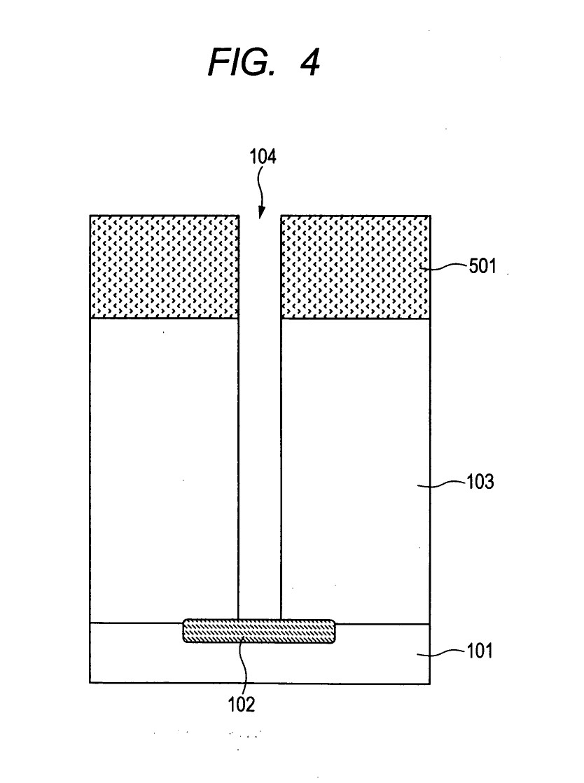

Next, using a known photolithography technique and etching technique, a through hole 104, for example having an opening diameter of 50 nm and a depth of 300 nm, is formed at a predetermined region in the interlayer insulating film 103 (FIG. 4, S103).

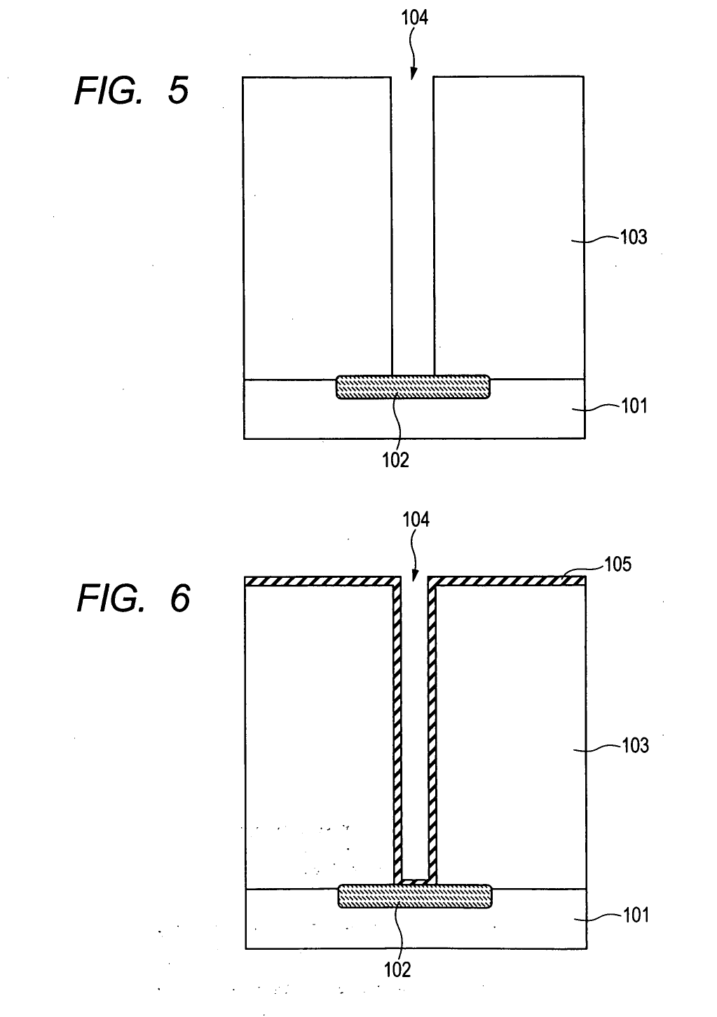

The resist film 501 is then removed by an ashing method (FIG. 5), and a metal layer 105 is formed on the sidewall and bottom of the through hole 104 (FIG. 6, S104). The metal layer 105 can be formed by depositing a metal, such as Co and Ti, through a PVD (Physical Vapor Deposition) method, CVD method or ALD (atomic layer deposition) method. The thickness of the metal layer 105 can be set, for example, to 10 nm. In addition, it is preferable to grow the metal layer 105 so as to have an hcp crystal structure or fcc crystal structure. In this embodiment, the metal layer 105 within the second region 12 is a second layer acting as a growth face of the Cu film 107.

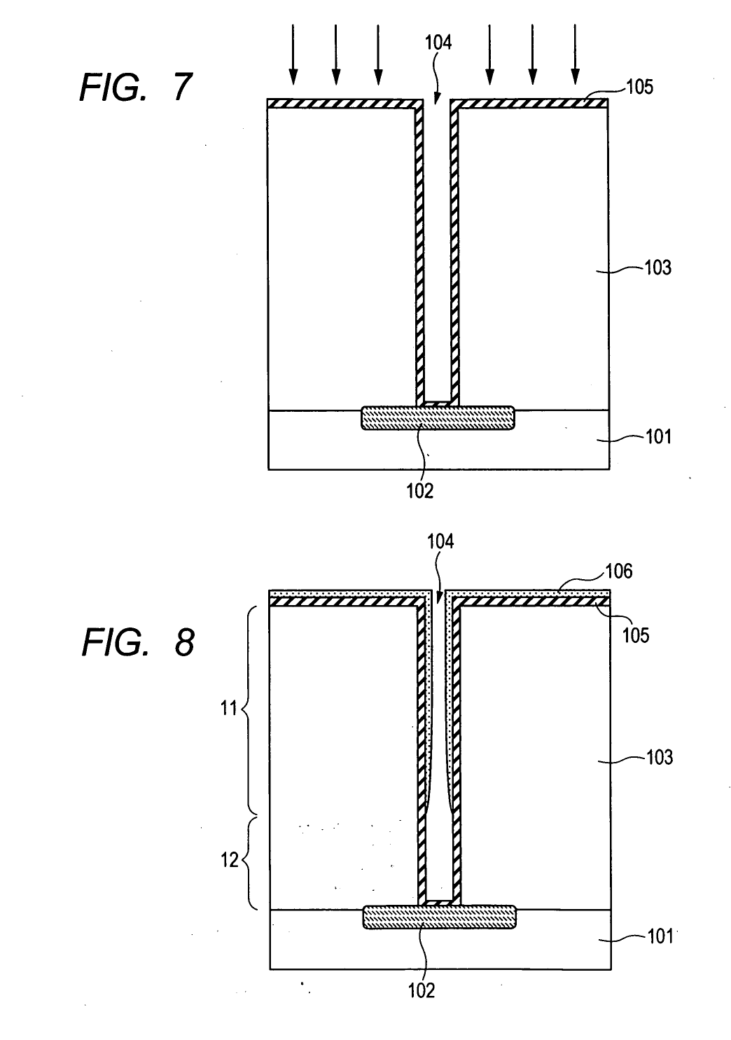

Subsequently, plasma containing nitrogen elements is generated with ammonia gas (NH3) or nitrogen gas (N2) as a reaction gas to subject the metal layer 105 on the top of the interlayer insulating film 103 and on a sidewall area, in the sidewall of the through hole, in the vicinity of the opening of the through hole 104 to plasma processing (FIG. 7). This processing forms a metal nitride layer 106 (first layer) over the upper surface of the interlayer insulating film 103 and on the sidewall area in the vicinity of the opening of the through hole 104 (FIG. 8, S105); however, the metal nitride layer 106 is not formed on the bottom and a sidewall area in the vicinity of the bottom of the through hole 104.

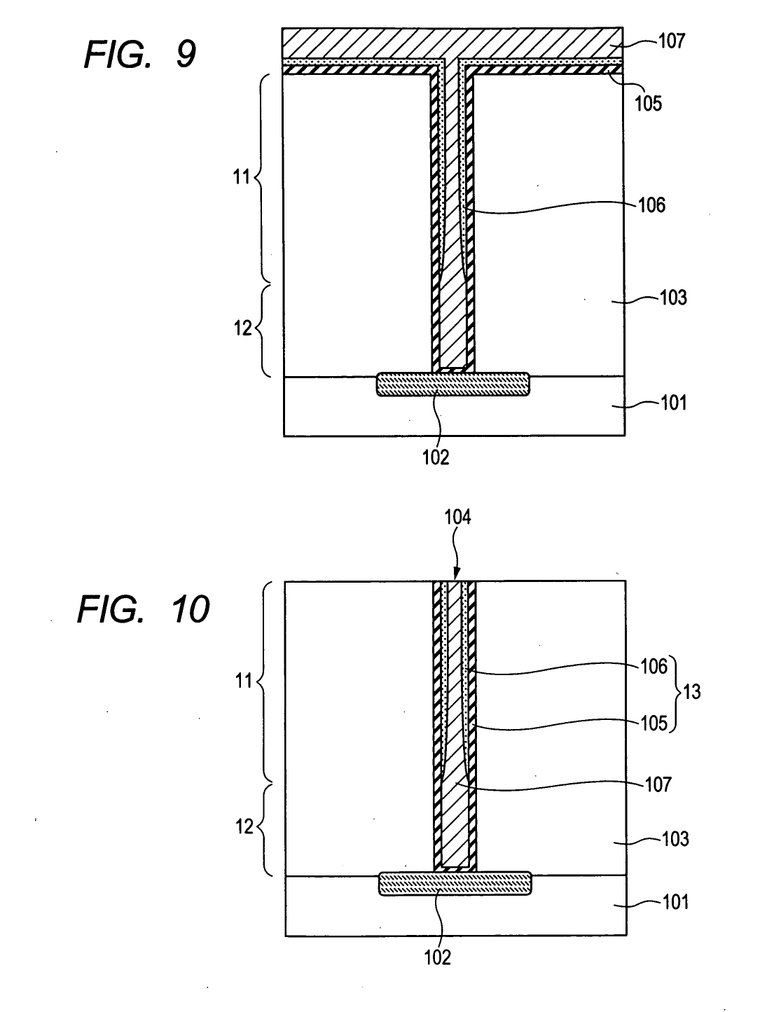

The through hole 104 is then filled with a Cu film 107 by a CVD method (S106). Since the growth of the Cu film 107 on the surface of the metal nitride layer 106 is retarded, the Cu can be filled from the bottom of the through hole 104 for the lesser grown Cu film 107 on the metal nitride layer 106 as shown in FIG. 9. The metal layer 105 having an fcc or hcp crystal structure accelerates the growth of the Cu film 107 in the second region 12, thereby more reliably filling the through hole 104 with Cu from the bottom.

As shown in FIG. 10, the Cu film 107, metal nitride layer 106 and metal layer 105 formed outside the through hole 104 are removed by a CMP method (S107). This removal completes the contact plug 1.

Furthermore, a multilayer interconnection structure is fabricated using a known multilayer interconnection technique (S108). Although FIG. 1 shows an interconnection structure 2 having a single layer for simplicity, the multilayer interconnection structure is fabricated with analogous layers deposited on each other. Specifically, a diffusion preventive film 116 is formed so as to cover the surface of the Cu film 107 filling the through hole 104, and an interlayer insulating film 117 is formed over the diffusion preventive film 116. Using a known lithography technique and etching technique, a trench is formed in the interlayer insulating film 117. After the surface of the trench is internally coated with a barrier metal film 119, the trench is filled with a Cu film to form a Cu interconnect 118. In this manner, the interlayer insulating-film formation process, trench formation process and Cu interconnect formation process are repeated to form a multilayer interconnection structure.

Following is a description about the effect of the embodiment. According to the embodiment, the Cu film 107 is formed over the contact-hole sidewall area adjacent to the opening of the through hole 104 with the metal nitride layer 106 used as a base, while the Cu film 107 is formed over the contact-hole sidewall area near the semiconductor substrate 101 with the metal layer 105 used as a base. The deposition rate of the Cu film 107 on the surface of the metal layer 105 is greater than the deposition rate of the Cu film 107 on the surface of the metal nitride layer 106. The deposition rate difference permits filling the Cu film 107 from the contact-hole sidewall area near the semiconductor substrate 101, thereby realizing a void/seam resistant structure.

FIG. 18 illustrates a resultant product formed by filling the through hole 104 with a Cu film 907 by a CVD method without using plasma processing on the metal layer 105 shown in FIG. 7. In other words, the base of the Cu film 907 in FIG. 18 is the metal layer 105. Similar to Japanese Unexamined Patent Publications No. 2008-130931, 2009-10037 and Hei 6 (1994)-112157, the base films, on which the Cu film 907 is formed, on the contact-hole sidewall area near the opening and contact-hole sidewall area near the bottom are made of the same material. As shown in FIG. 18, the Cu film 907 uniformly grows on the exposed surface of the metal layer 105; however, the Cu film grows thickest on the metal layer 105 on the top of the interlayer insulating film 103 and grows second thickest on the metal layer 105 near the opening of the through hole 104. As a result, pinch-off occurs inside the through hole or at the opening of the through hole, which leaves a void V and seam S in the through hole 104.

On the other hand, the plasma nitrided surface, by the plasma processing shown in FIG. 7, of the metal layer 105 near the opening of the through hole 104 and on the top of the interlayer insulating film 103 can retard the growth of the Cu film 107 near the opening of the through hole 104 and on the top of the interlayer insulating film 103. In addition, forming the metal layer 105 with an fcc structure or hcp structure can increase the deposition rate of the Cu film 107 formed on the surface of the metal layer 105. The Cu growth thus primarily starts from the lower part of the through hole 104 and bottom-up fill starting from the lower part of the through hole 104 can be achieved as shown in FIG. 9, thereby inhibiting the generation of the seam S and void V as shown in FIG. 18.

### Second Embodiment

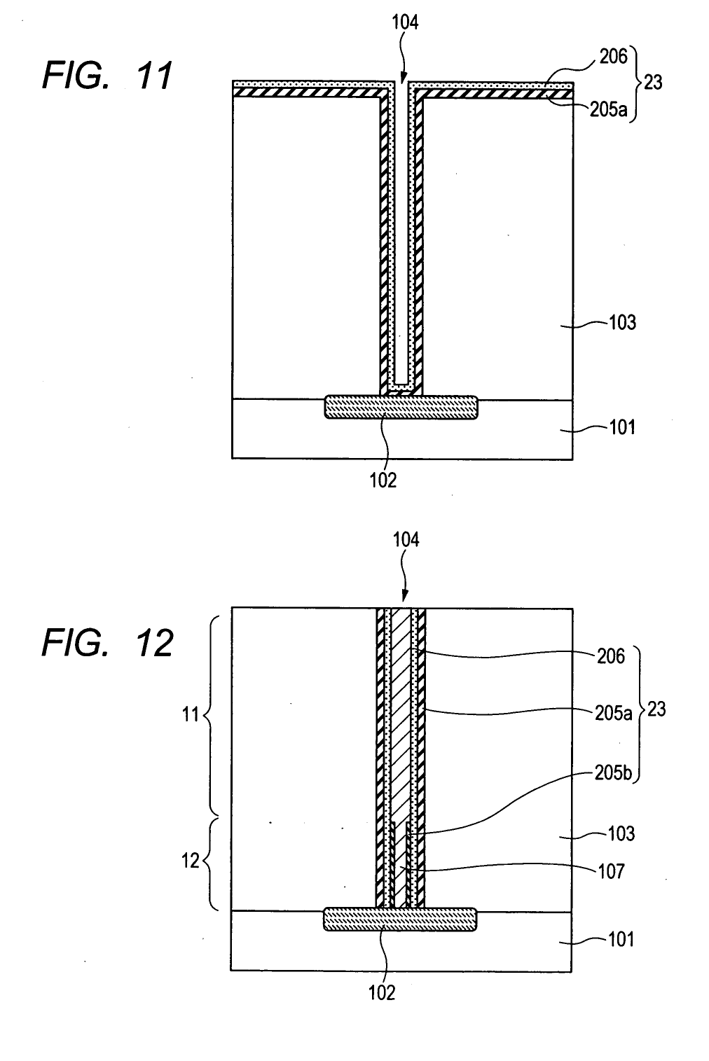

FIGS. 11 and 12 are schematic cross-sectional views illustrating a method for manufacturing a semiconductor device of the second embodiment. The semiconductor device manufactured according to the embodiment includes a metal-containing base film 23 that has a double layer structure formed of a metal layer 205a and a metal nitride layer 206 in a first region 11. The metal nitride layer 206 (first layer) is located at the interface with a Cu film 107. The metal-containing base film 23 has a triple layer structure formed of a metal layer 205a, a metal nitride layer 206 and a metal layer 205b in a second region 12. The metal layer 205b (second layer) is located at the interface with the Cu film 107. The deposition rate of the Cu film 107 on the surface of the metal layer 205b is greater than the deposition rate of the Cu film 107 on the surface of the metal nitride layer 206. In this embodiment, the metal-containing base film 23 is not formed on the bottom of the through hole 104, and the Cu film 107 is filled so as to make contact with a silicide layer 102. The other components are the same as those in the first embodiment.

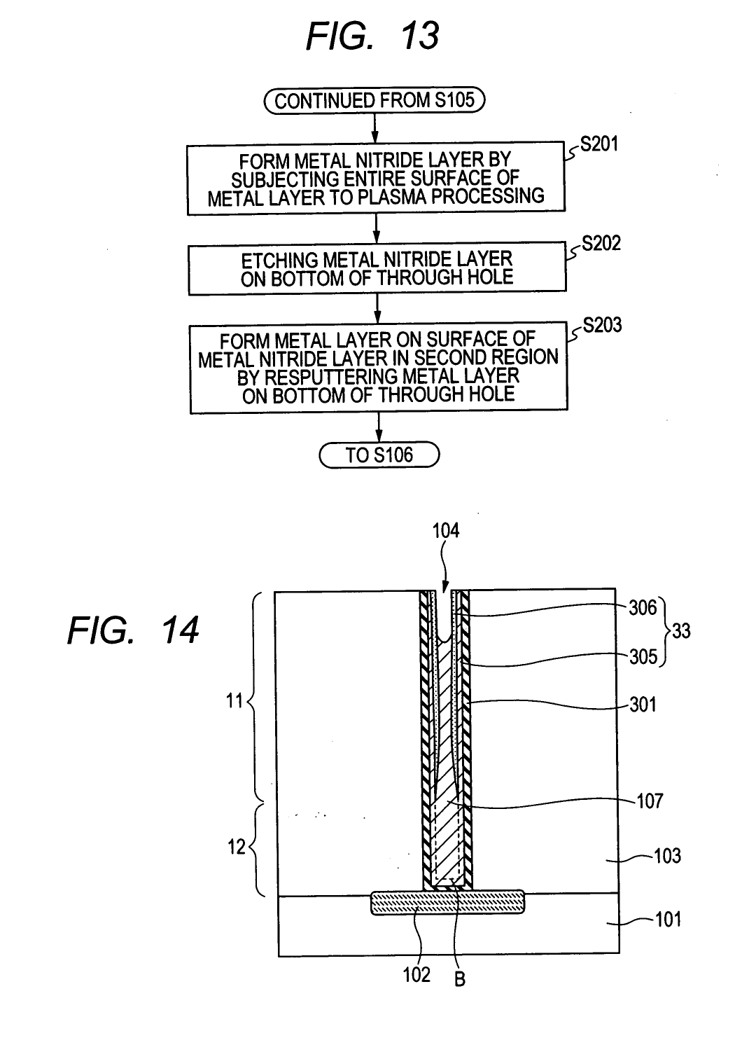

With reference to FIGS. 11 to 13, the method for manufacturing the semiconductor device of the embodiment will be described focusing only on the differences from the first embodiment. FIG. 13 is a flow chart describing a part of the manufacturing method of the embodiment. First of all, the metal layer 205a is formed on the sidewall and bottom of the through hole 104 (S101 to S104) as described with FIGS. 3 to 6.

Next, as described with FIG. 7, the surface of the metal layer 205a is subjected to plasma processing with nitrogen gas or ammonia gas as a source gas. In this embodiment, the metal layer 205a formed on the sidewall of the through hole 104 in the second region 12 and on the bottom of the through hole 104 is also subjected to the plasma processing (S201). This processing forms the metal nitride layer 206 on the entire surface of the metal layer 205a (FIG. 12).

Then, sputtering is performed with argon or the like to remove the metal nitride layer 206 on the bottom of the through hole 104, and the removed metal nitride layer 206 is resputtered onto the metal nitride layer 206 in the second region 12 (S202).

Subsequently, sputtering is performed with argon or the like to remove the exposed metal layer 205a on the bottom of the through hole 104, resulting in that the silicide layer 102 is exposed. The removed metal layer 205a is resputtered as a metal layer 205b onto the metal nitride layer 206 resputtered in S202 (S203).

Returning to S106 in FIG. 2, a Cu film 107 is formed by a CVD method, and the Cu film 107, metal nitride layer 206 and metal layer 205a formed outside the through hole 104 are removed by a CMP method, thereby completing the contact structure as shown in FIG. 12.

The Cu film 107 in this embodiment is also formed on the metal nitride layer 206 as a base in the first region 11, while the Cu film 107 is formed on the metal layer 205b as a base in the second region 12. The deposition rate of the Cu film 107 on the metal layer 205b by the CVD method is greater than the deposition rate of the Cu film 107 on the metal nitride layer 206. This allows the through hole 104 to be filled with the Cu film 107 from the sidewall area, in the sidewall of the through hole 104, near the semiconductor substrate 101, thereby realizing a void/seam resistant structure.

### Third Embodiment

FIG. 14 is a schematic cross-sectional view illustrating a method for manufacturing a semiconductor device of the third embodiment. The semiconductor device manufactured according to the embodiment, as shown in FIG. 14, includes a metal-containing base film 33 that has a double layer structure formed of a Cu layer 305 (second layer) and a copper nitride layer 306 (first layer) in a first region 11. In a second region 12 the metal-containing base film 33 includes a Cu layer 305 and has a regrowth interface B of Cu at the interface with a Cu film 107. The deposition rate of the Cu film 107 on the surface of the Cu layer 305 is greater than the deposition rate of the Cu film 107 on the surface of the copper nitride layer 306. A barrier metal film 301 is provided inside the through hole 104 to prevent Cu from diffusing into the interlayer insulating film 103. A silicide layer 102 makes contact with the barrier metal film 301, but not with the Cu layer 305. The other components are the same as those in the first embodiment.

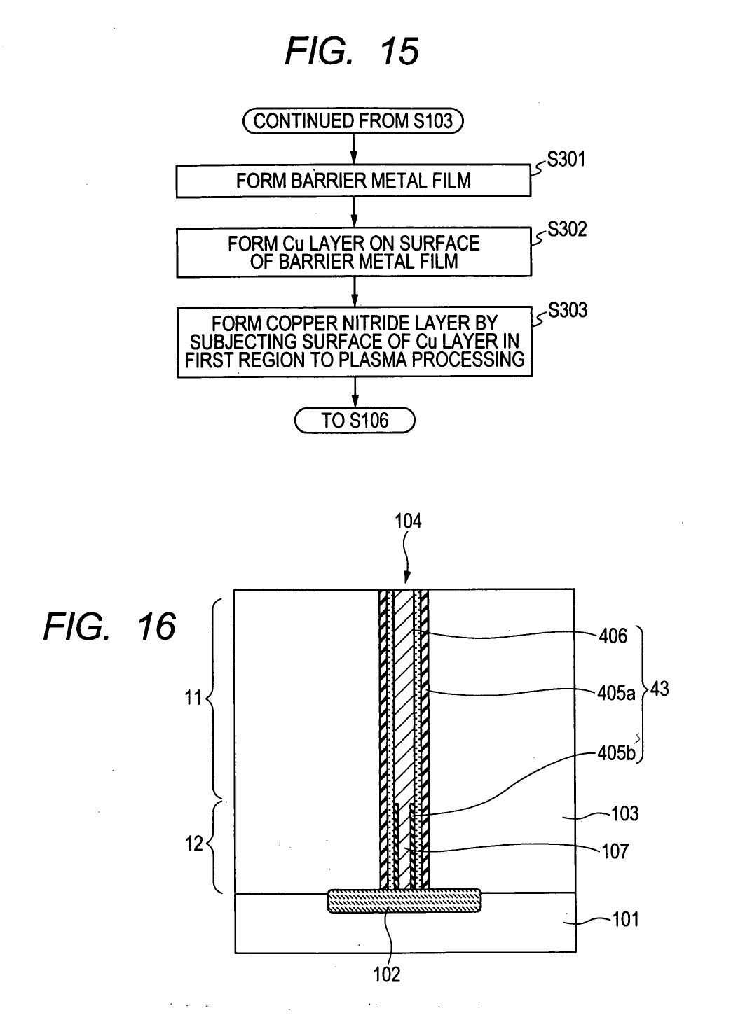

With reference to FIGS. 14 and 15, the method for manufacturing the semiconductor device of the embodiment will be described focusing only on the differences from the first embodiment. FIG. 15 is a flow chart describing a part of the manufacturing method of the embodiment. First of all, a through hole 104 is formed at a predetermined region in the interlayer insulating film 103 as described with FIGS. 3 to 5 (S101 to S103).

Next, a barrier metal film 301 is formed on the sidewall and bottom of the through hole 104 by a PVD method, CVD method or ALD method (S301). The barrier metal film 301 is made of, for example, TiN. Then, a thin Cu layer 305 is formed on the surface of the barrier metal film 301 by a CVD method (S302). The thickness of the Cu layer 305 is, for example, 5 nm.

Subsequently, plasma nitriding is subjected to the surface of the Cu layer 305 formed on the top of the interlayer insulating film 103 and the Cu layer 305 formed on the contact-hole sidewall area near the opening of the through hole 104 with a reaction gas, such as NH3 or N2. The plasma nitriding forms a copper nitride layer 306 on the upper surface of the interlayer insulating film 103 and the contact-hole sidewall area near the opening of the through hole 104, but does not form a copper nitride layer 306 on the bottom and the contact-hole sidewall area near the bottom of the through hole 104 (S303).

Returning to S106, the Cu film 107 is formed by the CVD method, and the Cu film 107, copper nitride layer 306 and Cu layer 305 formed outside the through hole 104 are removed by the CMP method to form a contact structure as shown in FIG. 14.

The deposition rate of the nitrided Cu film (copper nitride layer 306) by a CVD method is decreased compared with the pre-nitrided Cu. Accordingly, the Cu film primarily starts growing in the vicinity of the bottom of the through hole 104, thereby decreasing the generation of the seam S and void V as shown in FIG. 18.

### Fourth Embodiment

FIG. 16 is a schematic cross-sectional view illustrating a method for manufacturing a semiconductor device of the fourth embodiment. The semiconductor device manufactured according to the embodiment includes a metal-containing base film 43 that has a laminated structure including first metal layers 405a, 405b, which have an hcp crystal structure or fcc crystal structure, and a second metal layer 406, which has neither the hcp crystal structure nor fcc crystal structure. The first metal layer 405b is a second layer, while the second metal layer 406 is a first layer. The deposition rate of the Cu film 107 on the surface of the first metal layer 405b is greater than the deposition rate of the Cu film 107 on the surface of the second metal layer 406. The first metal layers 405a, 405b can be a film containing, for example, Co or Ti, and preferably a film containing 90% by weight of Co or Ti. The first metal layer 405a may be a single layer or has a multilayer structure. The second metal layer 406 is formed on the first metal layer 405a. The second metal layer 406 has neither hcp crystal structure nor fcc crystal structure, but may have, for example, a body-centered cubic structure (bcc structure). The second metal layer 406 can be a film containing, for example, Ta or W, and preferably a film containing 70% by weight of Ta or more. The metal-containing base film 43 in a first region 11 has a double-layer structure in which the second metal layer 406 is formed on the first metal layer 405a, while the metal-containing base film 43 in a second region 12 has a three-layer structure in which the first metal layer 405a, second metal layer 406 and first metal layer 405b are laminated. In this embodiment, the metal-containing base film 43 is not formed on the bottom of the through hole 104 so that the Cu film 107 makes contact with a silicide layer 102. The other components are the same as those in the first embodiment.

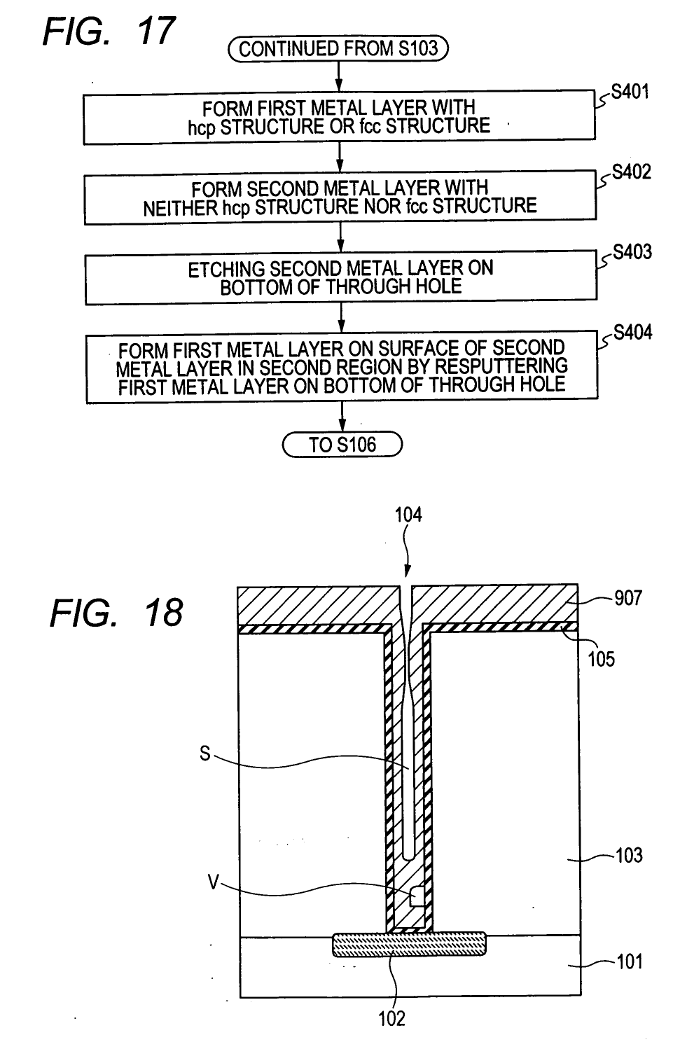

With reference to FIGS. 16 and 17, the method for manufacturing the semiconductor device of the embodiment will be described focusing only on the differences from the first embodiment. FIG. 17 is a flow chart describing a part of the manufacturing method of the embodiment. First of all, a through hole 104 is formed in a predetermined region over the semiconductor substrate 101 as described with FIGS. 3 to 5 (S101 to S103). Then, a first metal layer 405a having an hcp structure or fcc structure is formed by depositing a metal, such as Co or Ti, on the sidewall and bottom of the through hole 104 by a PVD method, CVD method or ALD method. The thickness of the first metal layer 405a is, for example, 10 nm (S401).

Next, Co is deposited on the entire surface of the first metal layer 405a by a PVD method, CVD method or ALD method to form the second metal layer 406 (S402). The second metal layer 406 is controlled under film forming conditions to have a bcc crystal structure so as not to have an hcp crystal structure and fcc crystal structure. The thickness of the second metal layer 406 is, for example, from 1 nm to 3 nm.

Then, sputtering is performed with argon or the like to remove the second metal layer 406 on the bottom of the through hole 104, and the removed second metal layer 406 is resputtered onto the second metal layer 406 in the second region 12 (S403).

Subsequently, sputtering is performed with argon or the like to remove the exposed first metal layer 405a on the bottom of the through hole 104, resulting in that the silicide layer 102 is exposed. The removed first metal layer 405a is resputtered as a first metal layer 405b onto the second metal layer 406 resputtered in S403 (S404).

The Cu film 107 is then formed by a CVD method, and the Cu film 107, second metal layer 406 and first metal layers 405a, 405b formed outside the through hole 104 are removed by a CMP method, thereby completing the contact structure as shown in FIG. 16.

In this embodiment, the Cu film 107 is formed on the second metal layer 406 as a base over a contact-hole sidewall area in the vicinity of the opening of the through hole 104 (in the first region 11). In addition, the Cu film 107 is formed on the first metal layer 405b as a base over a contact-hole sidewall area (in the second region 12) nearer to the semiconductor substrate 101 than is the first region 11. The first metal layers 405a, 405b have an hcp crystal structure or fcc crystal structure, while the second metal layer 406 has neither the hcp crystal structure nor fcc crystal structure. This crystal structure difference makes the deposition rate of the Cu film 107 formed on the first metal layer 405b by a CVD method greater than the deposition rate of the Cu film 107 formed on the second metal layer 406 by a CVD method. This deposition rate difference allows the through hole 104 to be filled with the Cu film 107 from the sidewall area near the semiconductor substrate 101, thereby realizing a void/seam resistant structure.

The embodiments of the present invention have been described with reference to the drawings; however, these embodiments are merely examples of the present invention and various structures other than the above-described structures are also applicable. For example, although the surface of the first metal layer is subjected to nitriding processing to form a metal nitride film in the embodiments, the surface of the first metal layer may be subjected to plasma oxidation processing with plasma containing oxygen elements generated by a reaction gas such as oxygen gas (O₂) or ozone gas (O₃) to form a metal oxide film as a second metal layer.

Although the through hole, which couples the transistor element and interconnects, is filled with a metal film in the embodiments, the present invention can be applied to metal-film filling techniques for via holes used to couple interconnects.

Although a single contact plug is used to couple a transistor element and an interconnect in the embodiments, the transistor element and interconnect can be coupled by stacking contact plugs. In this case, the metal filling up the through hole needs to be a Cu film for at least contact plugs with the highest aspect ratio, but can be other metal films, such as W (tungsten) film, for contact plugs with other aspect ratios.

Although holes including the through hole are filled with a Cu film in the embodiments, the present invention can be applied to hole filling techniques using metals other than Cu, for example, W, Co, Al (aluminum) or Ni (nickel).

Although the Cu film is a metal film mainly containing Cu in the embodiments, the Cu film can be made of Cu alone or can contain Al or the like as an impurity.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
an insulating film formed over a substrate;
a hole formed in the insulating film;
a metal film filling the hole; and
a metal-containing base film formed on a sidewall inside the hole and serving as a base of the metal film,
wherein in a first region including a sidewall area, in the sidewall inside the hole, adjacent to an opening of the hole, the metal-containing base film has a first layer at an interface with the metal film,
wherein in a second region including a sidewall area, in the sidewall inside the hole, nearer to the substrate than is the first region is, the metal-containing base film has a second layer at an interface with the metal film, and
wherein the deposition rate of the metal film on the surface of the second layer is greater than the deposition rate of the metal film on the surface of the first layer.

2. The semiconductor device according to claim 1,
wherein the metal film includes copper (Cu), and
wherein the deposition rate of the metal film is a deposition rate of a copper film formed by chemical vapor deposition.

3. The semiconductor device according to claim 1,
wherein the crystal structure of the second layer is a face centered cubic lattice structure or a hexagonal close-packed structure.

4. The semiconductor device according to claim 1,
wherein the metal-containing base film and the metal film include copper (Cu).

5. The semiconductor device according to claim 1,
wherein the metal-containing base film includes cobalt (Co) or titanium (Ti), and the metal film includes copper (Cu).

6. The semiconductor device according to claim 1,
wherein the first layer is a metal nitride film made by nitriding the metal-containing base film or a metal oxide film made by oxidizing the metal-containing base film.

7. The semiconductor device according to claim 1,
wherein the metal-containing base film is formed on the bottom of the hole.

8. The semiconductor device according to claim 1,
wherein the metal-containing base film is not formed on the bottom of the hole.

9. The semiconductor device according to claim 1,
wherein the metal-containing base film has a laminated structure including a first metal layer having a face centered cubic lattice crystal structure or hexagonal close-packed crystal structure and a second metal layer having neither the face centered cubic lattice crystal structure nor hexagonal close-packed crystal structure,
wherein the first metal layer has the same composition as that of the second layer,
wherein the second metal layer is the first layer, and
wherein the metal-containing base film is not formed on the bottom of the hole.

10. A method for manufacturing a semiconductor device comprising:
forming an insulating film over a substrate;
forming a hole in the insulating film; and
filling the hole with a metal film,
wherein after the forming the hole in the insulating film and before the filling the hole with the metal film, forming a metal-containing base film on a sidewall inside the hole is included, the metal-containing base film serving as a base of the metal film,
wherein the metal-containing base film has a first layer in a first region including a sidewall area, in the sidewall inside the hole, adjacent to an opening of the hole and a second layer in a second region including a sidewall area, in the sidewall inside the hole, nearer to the substrate than is the first region, and
wherein in the filling the hole with the metal film, the metal film is formed over the metal-containing base film so that the metal film on the surface of the second layer is formed at a deposition rate greater than that at which the metal film on the surface of the first layer is formed.

11. The method for manufacturing the semiconductor device according to claim 10,
wherein the metal film includes copper (Cu),
wherein the deposition rate of the metal film is a deposition rate of a copper film formed by chemical vapor deposition, and
wherein in the filling the hole with the metal film, the metal film is formed by chemical vapor deposition.

12. The method for manufacturing the semiconductor device according to claim 10,
wherein in the forming the metal-containing base film, the surface of the metal-containing base film in at least the first region is subjected to plasma processing with plasma containing nitrogen elements or oxygen elements to form the first layer made of a metal nitride film or a metal oxide film.

13. The method for manufacturing the semiconductor device according to claim 12,
wherein in the forming the metal-containing base film, the second layer is formed so as to have a crystal structure, a face centered cubic lattice structure or a hexagonal close-packed structure.

14. The method for manufacturing the semiconductor device according to claim 12,
wherein in the forming the metal-containing base film, the second layer is formed by depositing cobalt (Co) or titanium (Ti) over the insulating film, and
wherein in the filling the hole with the metal film, the copper is deposited on the surface of the first layer and second layer.

15. The method for manufacturing the semiconductor device according to claim 12,
wherein in the forming the metal-containing base film, the metal-containing base film is formed on the sidewall and bottom of the hole,
wherein the surface of the metal-containing base film in the first region is subjected to the plasma processing, while the surface of the metal-containing base film in the second region is subjected to the plasma processing, and
wherein the metal-containing base film formed on the bottom of the hole is removed by sputtering to form the second layer on the plasma-processed metal-containing base film.

16. The method for manufacturing the semiconductor device according to claim 12,
wherein the forming the metal-containing base film includes:
forming a barrier metal film on the sidewall and bottom of the hole; and
forming a copper layer on the barrier metal film, and
wherein the copper layer in the first region is subjected to plasma processing to form the first layer made of copper nitride or copper oxide.

17. The method for manufacturing the semiconductor device according to claim 10,
wherein the forming the metal-containing base film includes:
forming a first metal layer having a face centered cubic lattice structure or a hexagonal close-packed structure on the sidewall and bottom of the hole;
forming a second metal layer having neither the face centered cubic lattice structure nor hexagonal close-packed on the first metal layer; and
forming the second layer on the second metal layer by removing the first metal layer formed on the bottom of the hole through sputtering, and
wherein in the forming the second metal layer, the second metal layer formed in the first region is the first layer.
